(19) United States
(12) Patent Application Publication
(10) Pub. No.: US 2026/0237861 A1
(43) Pub. Date: Aug. 13, 2026

(54) WIRING MODULE

(71) Applicant: Yazaki Corporation, Tokyo (JP)

(72) Inventors: Masayoshi TAKAYANAGI, Shizuoka (JP); Sadaharu OKUDA, Shizuoka (JP); Hikaru SANO, Shizuoka (JP); Koki ADACHI, Shizuoka (JP); Ryoichi MURATA, Shizuoka (JP)

(73) Assignee: Yazaki Corporation, Tokyo (JP)

(21) Appl. No.: 19/530,496

(22) Filed: Feb. 5, 2026

(30) Foreign Application Priority Data
Feb. 7, 2025 (JP) 2025-019063

(51) Int. Cl. H01M 50/503; H01B 7/04; H01M 50/505; H05K 5/02; H05K 5/03

(52) U.S. Cl. CPC H01M 50/503; H01B 7/04; H01M 50/505; H05K 5/0221; H05K 5/0226; H05K 5/03

(57) ABSTRACT

A wiring module includes a wiring module case which has a wiring path provided with a wiring member and a connector which has a housing for fixing one end of the wiring member. The wiring module case has a case body which is provided with the wiring path and a cover which is provided on the case body and covers the wiring path. The cover has a cover body which is fixed to the case body and a hinge structure portion which is connected to the cover body on the connector side of the cover body via a hinge, is rotatably provided around an axis of the hinge between an open position and a closed position, and has a wiring member fixing portion for fixing the wiring member on one end side toward the connector by being separated from the wiring path.

### CROSS-REFERENCE TO RELATED APPLICATIONS

The present application claims priority to and incorporates by reference the entire contents of Japanese Patent Application No. 2025-019063 filed in Japan on February 7, 2025.

### BACKGROUND OF THE INVENTION

### 1. Field of the Invention

The present invention relates to a wiring module.

### 2. Description of the Related Art

As an example of a technology relating to a conventional wiring module and connector, Japanese Patent Application Laid-open No. JP 2019 - 192 336 A discloses a wiring module including a flat electric wire attached to a power storage element group in which a plurality of power storage elements are integrated and an electric wire side connector connected to the end of the flat electric wire and fitted into an equipment side connector provided in a control unit of the power storage element group. The flat electric wire has an extra length portion extending from the power storage element group, and a bend restricting plate is laminated on a part of the extra length portion. The bend restricting plate suppresses free movement of the extra length portion due to vibration or the like.

In such a wiring module, for example, the arrangement of the extra length portion of the wiring member may be set in consideration of the arrangement of peripheral components such as a cover of a battery pack, but there is room for further improvement in the arrangement of the extra length portion of the wiring member.

### SUMMARY OF THE INVENTION

The present invention has been made in view of the above circumstances, and an object thereof is to provide a wiring module capable of appropriately arranging an extra length portion of a wiring member.

In order to achieve the above mentioned object, a wiring module according to one aspect of the present invention includes a wiring member which is electrically connected to an electrode terminal of a battery cell constituting a battery module; a wiring module case which has a wiring path provided with the wiring member; and a connector which has a housing for fixing one end of the wiring member, wherein the wiring module case has a case body which is provided with the wiring path and a cover which is provided in the case body and covers the wiring path, and the cover has a cover body which is fixed to the case body and a hinge structure portion which is connected to the cover body via a hinge on the connector side of the cover body, is provided rotatably around an axis of the hinge between an open position and a closed position, and has a wiring member fixing portion fixing the wiring member on the one end side toward the connector by being separated from the wiring path.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a front view illustrating a schematic configuration in a state in which a wiring module including a connector according to an embodiment is assembled to a battery module and a hinge structure portion is in an open position;

FIG. 2 is a side view as viewed from a P direction in FIG. 1;

FIG. 3 is a front view illustrating a schematic configuration in a state in which the wiring module including the connector according to the embodiment is assembled to the battery module, the hinge structure portion is in a closed position, and the connector is fitted to the mating connector; and

FIG. 4 is a perspective view illustrating a schematic configuration of a wiring module according to a modification of the embodiment.

### DETAILED DESCRIPTION OF THE PREFERRED EMBODIMENTS

Hereinafter, an embodiment according to the present invention will be described in detail with reference to the drawings. Furthermore, the present invention is not limited by the embodiment. In addition, components in the following embodiments include those that can be easily replaced by those skilled in the art or those that are substantially the same.

### Embodiment

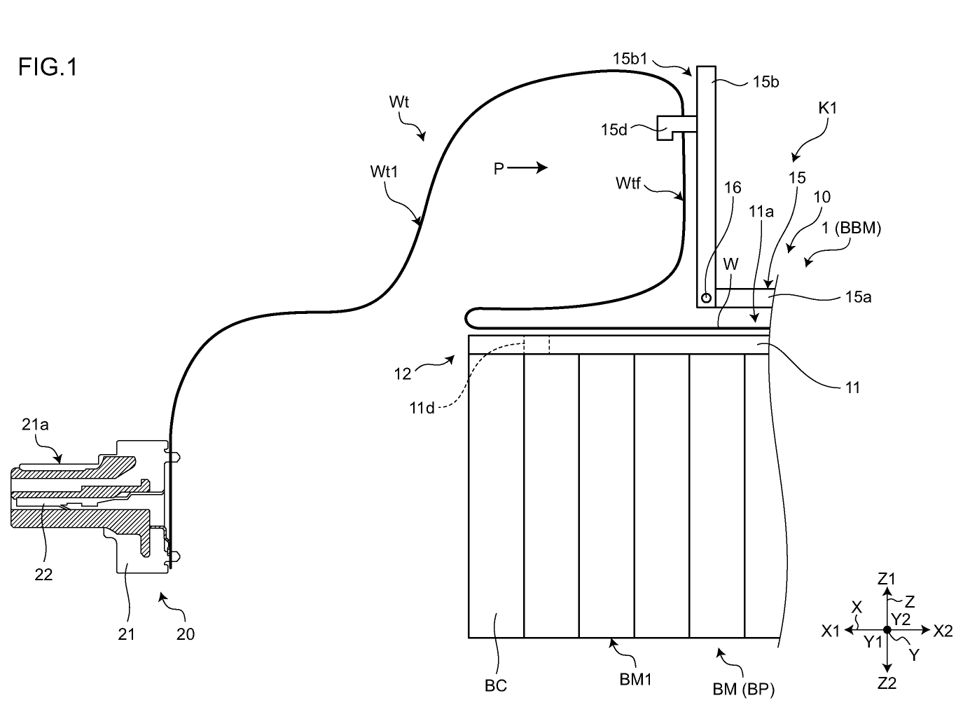

A wiring module 1 of the present embodiment illustrated in FIG. 1 is included in a busbar module BBM assembled to a battery module BM. The wiring module 1 includes a wiring module case 10, a wiring member W, and a connector 20. The plurality of battery cells BC constitute a battery module BM. The battery module BM is a component of the battery pack BP. The battery pack BP may have a plurality of battery modules BM. The battery pack BP is mounted as a power source in a vehicle such as an electric vehicle or a hybrid electric vehicle.

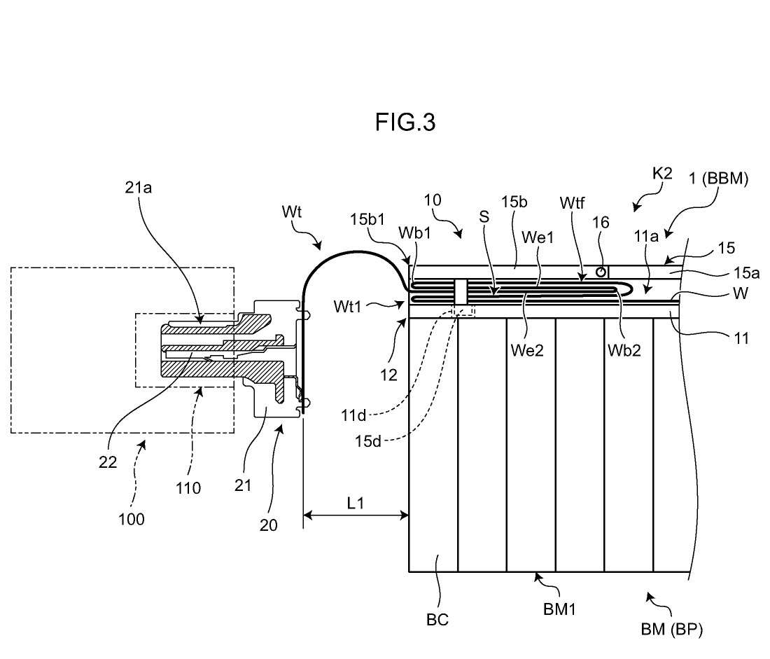

The busbar module BBM accommodates a plurality of busbars (not illustrated) electrically connected to a pair of electrodes (not illustrated) including a positive electrode terminal and a negative electrode terminal in each battery cell BC. The pair of electrodes of the plurality of battery cells BC is connected in parallel or in series by a plurality of busbars. The electrode terminal of each battery cell BC is electrically connected to the wiring member W via, for example, a voltage detection terminal (not illustrated). The voltage detection terminal is electrically connected to, for example, the busbar, and detects a voltage between the electrode terminals. The wiring member W electrically connected to the voltage detection terminal is electrically connected to a monitoring device 100 (see FIG. 3) via the connector 20. The connector 20 is formed as a female connector and is fitted to a connector 110 (mating connector) of the monitoring device 100 formed as a male connector. The voltage of each battery cell BC is monitored by the monitoring device 100.

In the following description, a direction in which the connector 20 is fitted to the connector 110 of the monitoring device 100 is referred to as a fitting direction X, and two directions orthogonal to and intersecting the fitting direction X are referred to as a width direction Y and a height direction Z. The height direction Z is a direction perpendicular to an installation surface BM1 of the battery module BM. In the following description, one side in the fitting direction X is referred to as one side X1, and the other side is referred to as the other side X2. Similarly, a description will be made such that the width direction Y is defined as one side Y1 (the front side of the sheet in FIGS. 1 and 3) and the other side Y2 (the rear side of the sheet in FIGS. 1 and 3), and the height direction Z is defined as one side Z1 and the other side Z2.

Although not illustrated, the positive and negative electrode terminals of the battery cell BC are arranged, for example, on one side Z1 in the height direction Z of the battery cell BC, one electrode terminal is provided on one side Y1 in the width direction Y, and the other electrode terminal is provided on the other side Y2. The busbar module BBM extends along the fitting direction X and is assembled to one side Z1 of the battery module BM in the height direction Z. The wiring module 1 of the busbar module BBM includes the wiring module case 10. The wiring module case 10 has a wiring path 11a in which the wiring member W is provided. The wiring module case 10 has a case body 11 provided with the wiring path 11a and a cover 15 provided in the case body 11 and covering the wiring path 11a.

The wiring member W extends in the direction along the fitting direction X in the wiring path 11a, and is, for example, a flat wiring member such as a flexible printed circuit (FPC) or a flexible flat cable (FFC). When the wiring member W is an FPC, the wiring member W has a base film, a coverlay, and a conductive layer. The base film and the coverlay are flexible insulating resin layers. The conductive layer is sandwiched and protected by the base film and the coverlay. The conductive layer is, for example, a conductive metal foil, and has a plurality of circuit patterns electrically connected to the above-described busbar (not illustrated) via a voltage detection terminal.

The wiring path 11a through which the wiring member W is wired extends along the fitting direction X in the case body 11. The case body 11 is fixed to a surface of the battery module BM on one side Z1 in the height direction Z. The wiring path 11a is provided, for example, between the electrode terminals of the positive electrode and the negative electrode in the width direction Y of the plurality of battery cells BC, and is formed in a substantially recessed groove shape. In the present embodiment, the wiring member W serving as the flat wiring member is wired with the flat surface oriented in the height direction Z. The wiring member W is wired in the wiring path 11a along the direction (that is, the fitting direction X) in which the wiring path 11a extends. The wiring path 11a is provided with a boss or a hook-shaped claw portion, and the wiring member W is fixed to the wiring path 11a.

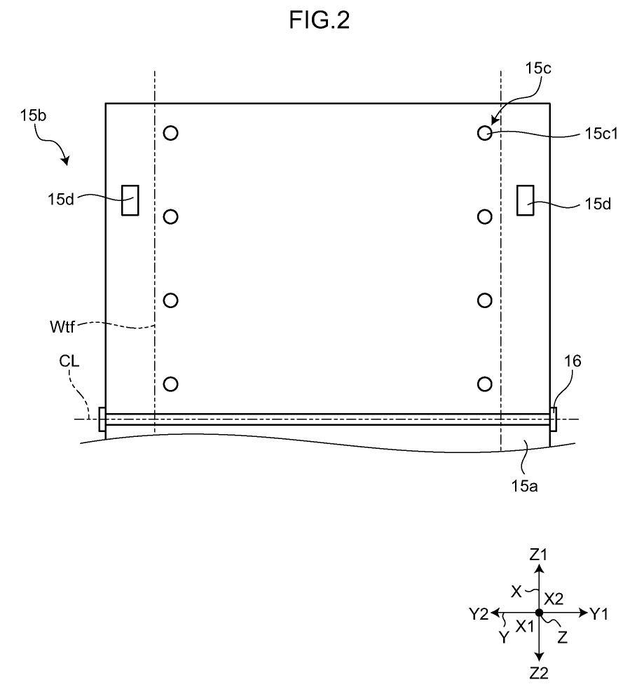

The cover 15 is provided on one side Z1 of the case body 11 in the height direction Z so as to cover the wiring path 11a. Both the case body 11 and the cover 15 can be formed in a substantially flat plate shape with the plate surface facing the height direction Z. The cover 15 has a cover body 15a fixed to the case body 11, and a hinge structure portion 15b connected to the cover body 15a via a hinge 16 on the connector 20 side (one side X1 in the fitting direction X) of the cover body 15a, and provided rotatably around an axis CL (see FIG. 2) of the hinge 16 between an open position K1 (see FIG. 1) and a closed position K2 (see FIG. 3). Furthermore, the open position K1 is a state in which the hinge structure portion 15b is opened to be separated from the case body 11, and the closed position K2 is a state in which the hinge structure portion 15b is closed to approach the case body 11.

In the cover body 15a, for example, a boss or the like is erected from the surface of the cover body 15a on the other side Z2 in the height direction Z, and the boss or the like is fixed to the case body 11 by being fixed to the surface of the case body 11 on the one side Z1 in the height direction Z, or the like. In addition, the wiring member W provided in the wiring path 11a is separated from the wiring path 11a at an outlet portion 12 on one side X1 in the fitting direction X in the wiring path 11a. The wiring member Wt on one side X1 in the fitting direction X separated from the wiring path 11a in the outlet portion 12 has a wiring member hinge fixing portion Wtf which is a portion fixed to the hinge structure portion 15b.

As illustrated in FIG. 1, the wiring member W is separated from the wiring path 11a at the outlet portion 12 and is folded back to the other side X2 (hinge 16 side) in the fitting direction X. As illustrated in FIG. 2, the folded wiring member W is fixed to a wiring member fixing portion 15c of the hinge structure portion 15b. That is, the hinge structure portion 15b has a wiring member fixing portion 15c that fixes the wiring member hinge fixing portion Wtf of the wiring member W on one end side (one side X1 in the fitting direction X) to the hinge structure portion 15b toward the connector 20 by being separated from the wiring path 11a.

Specifically, the wiring member fixing portion 15c can be, for example, a plurality of bosses respectively engaged with a plurality of through-holes provided at the edge of the wiring member W, a plurality of hook-shaped claw portions engaged with the edge of the wiring member W, or the like. FIG. 2 illustrates a plurality of bosses 15c1 as the wiring member fixing portion 15c. The wiring member fixing portion 15c is provided on a surface (surface on the other side Z2 in the height direction Z) of the hinge structure portion 15b on the case body 11 side at the closed position K2.

In addition, the hinge structure portion 15b is provided with a hinge structure portion side locking portion 15d. In the present embodiment, the hinge structure portion side locking portions 15d are provided at two positions facing each other with the wiring member W (wiring member hinge fixing portion Wtf) interposed therebetween in the width direction Y. On the other hand, the case body 11 has a case body side locking portion 11d to which the hinge structure portion side locking portion 15d is locked at the closed position K2 of the hinge structure portion 15b. The hinge structure portion side locking portion 15d is formed in, for example, a hook shape. For example, the case body side locking portion 11d is formed in a concave shape so that the hinge structure portion side locking portion 15d can be inserted. A protrusion may be provided on the concave inner surface of the case body side locking portion 11d to lock onto the hook-shaped jaw portion of the hinge structure portion side locking portion 15d. When the hinge structure portion side locking portion 15d and the case body side locking portion 11d are locked, the state of the hinge structure portion 15b is maintained at the closed position K2.

The wiring member W (wiring member Wt) extends outward from a distal end 15b1 of the hinge structure portion 15b. Here, the connector 20 has a housing 21 constituting a casing of the connector 20 and a plurality of terminals 22. One end of the wiring member W is fixed to the housing 21 of the connector 20. The housing 21 of the connector 20 is formed in a substantially rectangular box shape that is elongated in the width direction Y. One side X1 of the housing 21 in the fitting direction X is formed in a substantially rectangular tubular elongated in the width direction Y, and is a terminal holding portion 21a that holds the plurality of terminals 22. In the terminal holding portion 21a, the plurality of terminals 22 are arranged and held in the width direction Y.

Here, the connector 110 of the monitoring device 100 illustrated in FIG. 3 is provided with a terminal (not illustrated) serving as a male terminal. A terminal of the connector 110 is held by a substantially rectangular tubular hood portion (not illustrated) elongated in the width direction Y formed in the connector 110. The terminal holding portion 21a of the connector 20 is inserted into the hood portion of the connector 110 of the monitoring device 100 along the fitting direction X. When the terminal holding portion 21a is inserted into the hood portion of the connector 110, the terminal 22 of the connector 20 serving as the female terminal and the terminal of the connector 110 of the monitoring device 100 serving as the male terminal are fitted and electrically connected.

One end of the wiring member W (an end of the wiring member W on one side X1 in the fitting direction X) is fixed to the other side X2 in the fitting direction X of the housing 21 of the connector 20. The wiring member W is fixed to the housing 21 by, for example, a fixing member such as a peg for fixing the wiring member W to the housing 21. By fixing the wiring member W to the housing 21 of the connector 20, the plurality of terminals 22 of the connector 20 are electrically connected to the wiring member W.

The wiring member W is fixed from one side Z1 in the height direction Z of the housing 21 of the connector 20. Therefore, the wiring member W extends on one side Z1 in the height direction Z of the housing 21.

As described above, the connector 20 is fitted to the connector 110 of the monitoring device 100. The wiring member W has a margin in the length from the distal end 15b1 of the hinge structure portion 15b to the connector 20 at the open position K1 so that the connector 20 can be reliably fitted to the connector 110 of the monitoring device 100. That is, as illustrated in FIG. 3, the wiring member W has an extra length portion Wt1 (see also FIG. 1) which is excessively longer than the distance L1 from the distal end 15b1 of the hinge structure portion 15b to the connector 110 in a state in which the connector 20 is fitted to the connector 110 of the monitoring device 100. The extra length portion Wt1 is formed in a portion extending from the distal end 15b1 (more specifically, the wiring member fixing portion 15c on the distal end 15b1 side) of the hinge structure portion 15b in the wiring member Wt on one side X1 in the fitting direction X separated from the wiring path 11a in the outlet portion 12.

The fitting between the connector 20 and the connector 110 of the monitoring device 100 can be performed in a state in which the hinge structure portion 15b is in the open position K1 (see FIG. 1). After the connector 20 and the connector 110 of the monitoring device 100 are fitted to each other, the hinge structure portion 15b is set to the closed position K2, so that the extra length portion Wt1 is folded and accommodated between the hinge structure portion 15b and the case body 11. That is, the hinge structure portion 15b forms the accommodation space portion S for folding and accommodating the wiring member W on one end side from the wiring member fixing portion 15c toward the connector 20 between the hinge structure portion 15b and the case body 11 at the closed position K2.

The wiring member W (excess length Wt1) in the storage space S can be folded, for example, as illustrated in FIG. 3. That is, the wiring member W is bent toward the other side X2 in the fitting direction X at the distal end 15b1 (specifically, the wiring member fixing portion 15c on the distal end 15b1 side) of the hinge structure portion 15b to form a first bent portion Wb1. The wiring member W bent at the first bent portion Wb1 is a first extension portion We1 extending by a predetermined distance to the other side X2 in the fitting direction X. The second bent portion Wb2 is formed on the wiring member W of the first extension portion We1, and the wiring member W is further bent toward one side X1 in the fitting direction X. The wiring member W bent at the second bent portion Wb2 is a second extension portion We2 extending by a predetermined distance in the accommodation space portion S. The wiring member W of the second extension portion We2 extends outward from the outlet portion 12 toward the connector 20.

In the above example, the wiring member W (extra length portion Wt1) forms two bent portions (first bent portion Wb1, second bent portion Wb2) and two extension portions (first extension portion We1, second extension portion We2). For example, when the extra length portion Wt1 is further longer, four or more bent portions can be formed. An even number of bent portions is formed. The case where the extra length portion Wt1 is changed can be handled in this manner.

### Modification

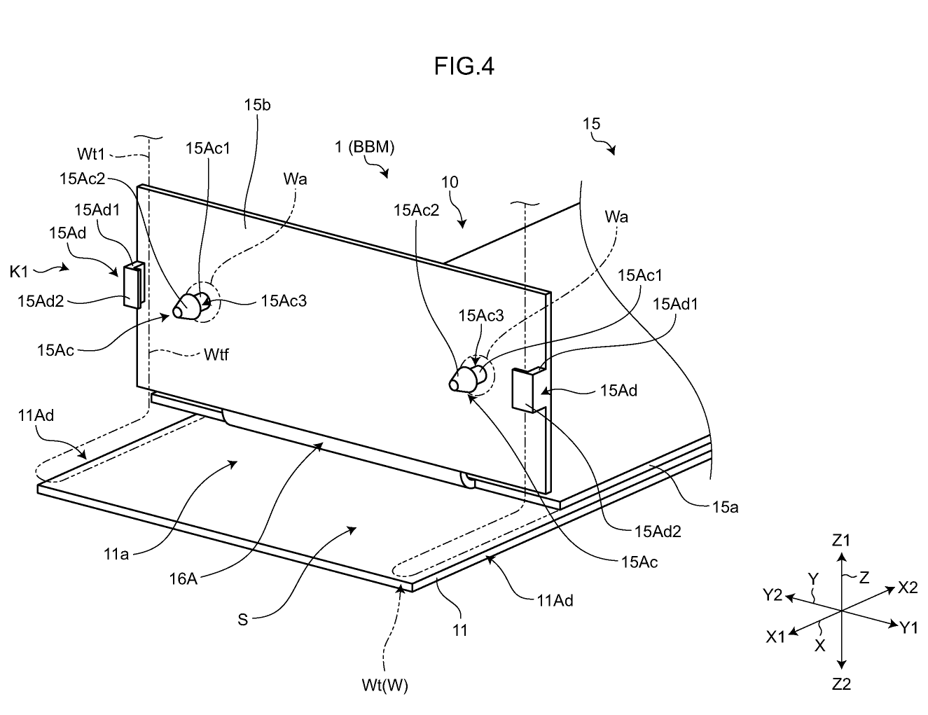

A modification of the present embodiment will be described with reference to FIG. 4. In FIG. 4, the wiring member fixing portion 15c and the hinge structure portion side locking portion 15d in the hinge structure portion 15b of the wiring module case 10 described above are respectively made into a wiring member fixing portion 15Ac and a hinge structure portion side locking portion 15Ad having a more specific shape. A hinge 16A of the wiring module case 10 in FIG. 4 is formed in a thin plate shape. In FIG. 4, illustration of the battery cells BC (battery module BM, battery pack BP), the connectors 20, and the like is omitted.

The wiring member fixing portion 15Ac is provided in a protruding shape on a surface (surface on the other side Z2 in the height direction Z) of the hinge structure portion 15b on the case body 11 side at the closed position K2. In the present modification, a total of two wiring member fixing portions 15Ac are provided on each of one side Y1 and the other side Y2 in the width direction Y so as to face each other in the width direction Y. The wiring member fixing portion 15Ac is erected from the hinge structure portion 15b and has a shaft portion 15Ac1 formed in a columnar shape and a distal end 15Ac2 provided at a tip of the shaft portion 15Ac1 and having a substantially truncated conical shape. The distal end 15Ac2 is connected to the shaft portion 15Ac1 such that the shaft portion 15Ac1 side is a large diameter side. The diameter of the distal end 15Ac2 on the large diameter side is sufficiently larger than the diameter of the shaft portion 15Ac1, and a locking step portion 15Ac3 is formed.

In addition, the hinge structure portion side locking portion 15Ad has a plate-shaped support plate 15Ad1 erected from the edges of the one side Y1 and the other side Y2 in the width direction Y of the hinge structure portion 15b, and a locking plate 15Ad2 protruding inward from the support plate 15Ad1. The support plate 15Ad1 and the locking plate 15Ad2 are formed in a substantially elongated rectangular plate shape elongated in the extending direction of the wiring member W. The support plate 15Ad1 is disposed with the plate surface facing the width direction Y. The locking plate 15Ad2 is disposed such that the plate surface is substantially parallel to the hinge structure portion 15b.

In the hinge structure portion side locking portion 15Ad, the locking plate 15Ad2 is positioned on the other side Z2 in the height direction Z of the edge of the plate-shaped case body 11 at the closed position K2, so that the hinge structure portion 15b is locked to the case body 11. Therefore, the edge of the case body 11 corresponding to the hinge structure portion side locking portion 15Ad at the closed position K2 is the case body side locking portion 11Ad. Furthermore, the wiring member W can be fixed so as to be sandwiched between the two hinge structure portion side locking portions 15Ad provided to face each other in the width direction Y.

The extra length portion Wt1 of the wiring member W can be provided with a hole portion Wa that can be fitted into the locking step portion 15Ac3 of the wiring member fixing portion 15Ac in advance. The wiring member Wt of the portion on one side X1 in the fitting direction X of the wiring member W including the extra length portion Wt1 can be fixed by fitting the hole portion Wa into the locking step portion 15Ac3 of the wiring member fixing portion 15Ac after fitting the connector 20 into the connector 110 of the monitoring device 100. Thereafter, the hinge 16A is rotated to set the hinge structure portion 15b to the closed position K2, and the wiring member Wt including the extra length portion Wt1 can be folded and accommodated in the accommodation space portion S. For example, the plurality of hole portions Wa can be provided at positions corresponding to the first extension portion We1 and the second extension portion We2 of the extra length portion Wt1 to be folded.

The wiring module 1 described above has the wiring member W which is electrically connected to the electrode terminals of the battery cells BC constituting the battery module BM, the wiring module case 10 which has the wiring path 11a provided with the wiring member W, and the connector 20 which has the housing 21 for fixing one end of the wiring member W thereto. The wiring module case 10 has the case body 11 which is provided with the wiring path 11a and the cover 15 which is provided on the case body 11 and covers the wiring path 11a. The cover 15 has the cover body 15a fixed to the case body 11 and the hinge structure portion 15b connected to the cover body 15a via the hinge 16 on the connector 20 side of the cover body 15a, provided rotatably around the axis CL of the hinge 16 between the open position K1 and the closed position K2, and including the wiring member fixing portion 15c fixing the wiring member W on one end side toward the connector 20 by being separated from the wiring path 11a.

As a result, after the connector 20 to which the wiring member W is fixed is fitted to the connector 110 of the monitoring device 100 which is the mating connector, the extra length portion Wt1 is folded along the hinge structure portion 15b by rotating and closing the hinge structure portion 15b from the open position K1 to the closed position K2. In this way, the extra length portion Wt1 of the wiring member W can be appropriately arranged. By appropriately disposing the extra length portion Wt1, the wiring member W is protected, and disconnection due to interference between members and devices around the battery pack BP (battery module BM) such as the cover of the battery pack BP and the extra length portion Wt1 of the wiring member W is reduced. In addition, since the extra length portion Wt1 can be folded by the rotation operation of the hinge structure portion 15b which is easy to work, the number of work steps for folding the extra length portion Wt1 can be reduced.

In addition, the hinge structure portion 15b forms, between the hinge structure portion 15b and the case body 11 at the closed position K2, the accommodation space portion S in which the wiring member W on one end side (one side X1 in the fitting direction X in the wiring member W) from the wiring member fixing portion 15c toward the connector 20 is folded and accommodated. Accordingly, since the extra length portion Wt1 of the folded wiring member W is accommodated in the accommodation space portion S, the extra length portion Wt1 can be disposed inside the wiring module 1 to protect the wiring member W.

In addition, the hinge structure portion 15b has the hinge structure portion side locking portions 15d and 15Ad, and the case body 11 has the case body side locking portions 11d and 11Ad to which the hinge structure portion side locking portions 15d and 15Ad are locked at the closed position K2 of the hinge structure portion 15b. As a result, it is possible to maintain the folded state of the extra length portion Wt1 of the wiring member W, and thus, for example, in a case where the wiring module 1 is assembled to the battery pack BP mounted on the vehicle, it is reduced that the hinge structure portion 15b is unintentionally positioned at the open position K1 due to the vibration and the folded extra length portion Wt1 returns to the original state. In particular, when the FPC having a strong repulsive force is adopted as the wiring member W, the hinge structure portion 15b can appropriately maintain the closed position K2 by locking the hinge structure portion side locking portions 15d and 15Ad and the case body side locking portions 11d and 11Ad.

Furthermore, the wiring module 1 according to the embodiment of the present invention described above is not limited to the embodiment described above, and various modifications can be made within the scope described in the claims.

In the above description, the one side Y1 and the other side Y2 in the width direction Y between the cover 15 and the case body 11 (a gap including the accommodation space S) are opened, but a cover or the like may be separately provided. In addition, the positions of the distal end 15b1 and the outlet portion 12 of the hinge structure portion 15b in the fitting direction X are aligned in the present embodiment, but may not be aligned. In addition, the wiring module case 10 can be provided with a structure in which the hinge structure portion 15b maintains the open state at the open position K1, for example, a lock mechanism that locks the hinge 16 at the open position K1. In addition, the length of the hinge structure portion 15b in the width direction Y is formed to be the same as the width of the cover body 15a, but can be appropriately set in accordance with the length of the wiring member W in the width direction Y.

The wiring module according to the present embodiment may be configured by appropriately combining the components of the embodiment and the modifications described above.

The wiring module according to the present embodiment has an effect that the extra length portion of the wiring member can be appropriately arranged.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wiring module comprising:
a wiring member which is electrically connected to an electrode terminal of a battery cell constituting a battery module;
a wiring module case which has a wiring path provided with the wiring member; and
a connector which has a housing for fixing one end of the wiring member, wherein
the wiring module case has a case body which is provided with the wiring path and a cover which is provided in the case body and covers the wiring path, and
the cover has a cover body which is fixed to the case body and a hinge structure portion which is connected to the cover body via a hinge on the connector side of the cover body, is provided rotatably around an axis of the hinge between an open position and a closed position, and has a wiring member fixing portion fixing the wiring member on the one end side toward the connector by being separated from the wiring path.

2. The wiring module according to claim 1, wherein
the hinge structure portion forms an accommodation space portion for folding and accommodating the wiring member on the one end side from the wiring member fixing portion toward the connector between the hinge structure portion and the case body at the closed position.

3. The wiring module according to claim 1, wherein
the hinge structure portion has a hinge structure portion side locking portion, and
the case body has a case body side locking portion to which the hinge structure portion side locking portion is locked at the closed position of the hinge structure portion.

4. The wiring module according to claim 2, wherein
the hinge structure portion has a hinge structure portion side locking portion, and
the case body has a case body side locking portion to which the hinge structure portion side locking portion is locked at the closed position of the hinge structure portion.
